(19) United States
(12) Patent Application Publication
(10) Pub. No.: US 2024/0292637 A1
(43) Pub. Date: Aug. 29, 2024

(54) PEROVSKITE TANDEM SOLAR CELLS BASED ON A TUNNELING LAYER OF TWO-DIMENSIONAL LAYERED METAL CARBIDES AND METAL NITRIDES

(71) Applicant: HEFEI UNIVERSITY OF TECHNOLOGY, Hefei City (CN)

(72) Inventors: Yang JIANG, Hefei City (CN); Jingting YANG, Hefei City (CN); Guoqing TONG, Hefei City (CN)

(73) Assignee: HEFEI UNIVERSITY OF TECHNOLOGY, Hefei City, AH (CN)

(21) Appl. No.: 18/652,841

(22) Filed: May 2, 2024

(30) Foreign Application Priority Data
Nov. 28, 2023 (CN) 2023116001361

(51) Int. Cl. H10K 30/40; H10K 30/15; H10K 30/57; H10K 71/12

(52) U.S. Cl. CPC H10K 30/40; H10K 30/15; H10K 30/57; H10K 71/125

(57) ABSTRACT

The invention relates to a perovskite tandem solar cell based on a tunneling layer of two-dimensional layered metal carbides and metal nitrides, the tunneling junction composite layer is prepared by using two-dimensional layered metal carbides and metal nitrides, a dense layer is arranged on one side of the tunneling junction composite layer, and a transport layer is arranged on the other side. The two-dimensional layered metal carbide and metal nitride materials are selected from graphene, Ti3C2Tx, Mo2CTx, V2CTx, Nb2CTx and Ti2CTx. The tunneling junction structure of the invention can effectively reduce the light loss in the tandem solar cell and the interface recombination of the tandem cell, which can significantly improve the photocurrent generation and charge transfer of the perovskite/perovskite tandem solar cell, and improve the power conversion efficiency of the perovskite/perovskite tandem solar cell.

### TECHNICAL FIELD

The invention belongs to the field of solar cell technology, and specifically relates to a perovskite tandem solar cell based on a tunneling layer of two-dimensional layered metal carbides and metal nitrides.

### BACKGROUND ART

After years of development, perovskite tandem solar cells have developed different types of photovoltaic cells, including crystalline silicon cells, thin film cells, dye-sensitized solar cells and small organic molecule cells, and some of them have been commercialized. Hybrid Organic-Inorganic Perovskite Solar Cells, as a new member of the photovoltaic cell family, are considered to be a strong competitor for the next generation of perovskite tandem solar cells because of their high power conversion efficiency, simple operation, low cost and adjustable band structure, and they have achieved a certified efficiency of 26.14%, which is comparable to commercial silicon solar cells. However, the conversion efficiency of single junction solar cells is limited by the Shockley-Queisser (S-Q) efficiency limit.

In order to further improve the power conversion efficiency of perovskite solar cells, we construct a Perovskite Tandem Solar Cell with a tandem structure, that is, a wide band gap perovskite film is used as the light absorption layer of the top cell to achieve optical absorption in the short band (300-700 nm); the narrow band gap perovskite film is used as the optical absorption layer of the bottom cell to realize the optical absorption of the long band (700-1200 nm). Based on the tandem structure of wide band gap perovskite/narrow band gap perovskite, the utilization of solar spectrum by solar cells can be improved, the thermal relaxation loss of carriers in single junction solar cells can be reduced, and the power conversion efficiency of perovskite tandem solar cells can be further improved. However, a layer of tunneling structure is needed between the wide band gap perovskite solar cell and the narrow band gap perovskite solar cell to achieve the effect of connecting two sub-cells in series. At present, the common tunneling layer is mainly a composite layer of metal oxide semiconductors (such as SnO₂) and metal electrodes (such as gold or silver). The thicker metal electrode film has good conductivity, but the metal film has a certain light reflection and poor light transmittance, which will reduce the optical absorption of the incident light by the bottom perovskite solar cell. The ultra-thin metal electrode, although the light transmittance has been improved, it is difficult to achieve the continuity of the metal film, resulting in a lower conductivity of the tunneling junction layer.

### SUMMARY

The purpose of the invention is to solve the problems of poor conductivity and low transmittance of the tunneling layer in the existing perovskite/perovskite tandem solar cell, and to provide a solar cell based on a tunneling layer of two-dimensional layered metal carbides and metal nitrides. Two-dimensional layered metal carbide and metal nitride materials have metal-like properties (referred to as two-dimensional layered metal-like materials), which not only have very good electrical conductivity, but also have excellent light transmittance. The tunneling junction composite layer of this structure can not only transmit charges and carriers quickly, but also reduce light loss, which can improve the photoelectric performance of perovskite/perovskite tandem cells and simplify the preparation process. At the same time, this method can also be applied to the large-area modular preparation of perovskite/perovskite tandem solar cells.

In order to achieve the above invention purpose, the invention adopts the following technical means:

the invention is a solar photovoltaic cell based on a tunneling layer of two-dimensional layered metal carbides and metal nitrides, a tunneling junction composite layer is prepared by using two-dimensional layered metal carbides and metal nitrides, a dense layer is arranged on one side of the tunneling junction composite layer, and a transport layer is arranged on the other side.

The two-dimensional layered metal carbide and metal nitride materials include but are not limited to graphene, Ti₃C₂Tₓ, Mo₂CTₓ, V₂CTₓ, Nb₂CTₓ, Ti₂CTₓ, etc.

Furthermore, the tunneling junction composite layer is a continuous two-dimensional layered structure of metal carbide and metal nitride material film, a two-dimensional layered structure of metal carbide and metal nitride material particle film or a non-dense two-dimensional layered structure of metal carbide and metal nitride material island nanosheet layer.

Furthermore, the solar cell is perovskite/perovskite tandem solar cell.

The dense layer is prepared by n-type semiconductor materials, and the transport layer is prepared by p-type semiconductor materials. Or, the dense layer is prepared by p-type semiconductor materials, and the transport layer is prepared by n-type semiconductor materials.

The structure of the perovskite/perovskite tandem solar cell described in this paper is p-i-n type, which includes conductive substrate, p-type hole transport layer, wide band gap perovskite film, n-type electron transport layer, n-type dense layer, tunneling junction composite layer, p-type hole transport layer, narrow band gap perovskite film, n-type electron transport layer and metal back electrode from bottom to top.

Specifically, in the p-i-n structure:

the transparent conductive substrates are indium tin oxide (ITO) and fluorine-doped indium tin oxide (FTO), but not limited to the above listed.

The n-type dense layer or electron transport layer can be made of one or more n-type semiconductor materials such as titanium oxide (TiO₂), tin oxide (SnO₂), zinc oxide (ZnO), vanadium oxide (V₂O₅), zinc oxide tin (Zn₂SO₄), but not limited to the n-type semiconductor materials listed above.

The p-type hole transport layer can be prepared by one or more p-type semiconductor materials such as Nickel oxide (NiO), molybdenum oxide (MoO₃), cuprous oxide (Cu₂O), copper iodide (CuI), copper phthalocyanine (CuPc), cuprous thiocyanate (CuSCN), redox graphene, poly [bis(4-phenyl)(2,4,6-trimethylphenyl)amine] (PTAA),2,2′,7,7′-tetra[N,N-bis(4-methoxyphenyl)amino]-9,9′-spirobifluorene(Spiro-OMeTAD), 3,4-ethylenedioxythiophene: polystyrene sulfonate (PEDOT:PSS), 4-butyl-N, N-diphenylaniline homopolymer (PloyTPD), and polyvinyl carbazole (PVK), but not limited to the p-type semiconductor materials listed above.

Or, the structure of the perovskite/perovskite tandem solar cell is n-i-p type, which includes transparent conductive substrate, n-type electron transport layer, wide band gap perovskite film, p-type hole transport layer, p-type dense layer, tunneling junction composite layer, n-type electron transport layer, narrow band gap perovskite film, p-type hole transport layer and metal back electrode from bottom to top.

Specifically, in the n-i-p structure:

The p-type dense layer or hole transport layer can be prepared by one or more p-type semiconductor materials such as nickel oxide (NiO), molybdenum oxide (MoO₃), cuprous oxide (Cu₂O), copper iodide (CuI), copper phthalocyanine (CuPc), cuprous thiocyanate (CuSCN), but not limited to the p-type semiconductor materials listed above.

The n-type electron transport layer can be made of one or more n-type semiconductor materials such as titanium oxide (TiO₂), tin oxide (SnO₂), zinc oxide (ZnO), fullerene (C₆₀), graphene, fullerene derivative [6,6]-phenyl-C61-butyric acid methyl ester (PCBM), but not limited to the n-type semiconductor materials listed above.

In the two-dimensional layered metal carbide and metal nitride materials:

the preparation of Ti₃C₂Tₓ two-dimensional layered structure includes the following steps:

Step 1: firstly, under the protection of nitrogen in the glove box, weighing the drugs according to the ratio of TiC:Ti:Si:NaCl:KCl=2:1:1.1:4:4. Then, thoroughly mixing the weighed raw materials, and taking out the obtained mixed powder from the glove box and putting it into the planetary ball mill to fully mash for 5 h, and putting the mashed powder into the alumina crucible; then putting the alumina crucible into a tube furnace, and completing the reaction by heat treatment at a rate of 4° C./min to 1100° C. for 3 h under the protection of argon atmosphere. After the reaction, cooing the tube furnace to the room temperature at a rate of 4° C./min, and then removing NaCl and KCl by washing with deionized water, drying the residual product at 60° C. to obtain the Si-MAX phase precursor.

Step 2: under the protection of nitrogen in the glove box, thoroughly mixing the raw materials according to the molar ratio of Si-MAX phase precursor:ZnCl₂=1:6, and then taking out the obtained mixed powder from the glove box and placing it in a planetary ball mill for 3 h, and then placing the powder in an alumina crucible; putting the alumina crucible into a tube furnace and conducting heat treatment at 550° C. for 5 h under argon protection; after the reaction, removing the residual ZnCl₂ by washing with deionized water, and obtaining the reaction product Ti₃SiC₂MAX phase by drying at 40° C.

Step 3: immersing the prepared Ti₃SiC₂ MAX phase in molten CuCl₂ Lewis molten salt at 750° C. for 6 h, the Si atoms weakly bound to Ti in the Ti₃C₂ sublayer, which are oxidized to Si⁴⁺ cation by Lewis acid Cu²⁺, so as to form a volatile SiCl₄ phase. At the same time, Cu²⁺ is reduced to Cu metal, Ti₃SiC₂ reacts with CuCl₂ to form Ti₃C₂Tₓ MXene. The process includes the following reactions:

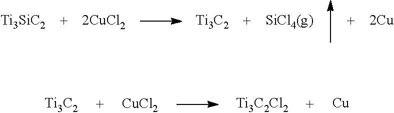

Ti₃C₂Cl₂ powder and Cu metal are further immersed in ammonium persulfate (APS, (NH₄)₂S₂O₈) solution to remove Cu particles on the surface of Ti₃C₂X₂ MXene and increase O-surface groups. The final materials prepared by this molten salt route is named MS-Ti₃C₂Tₓ MXene, where Tₓ represents the surface groups of O and Cl, and MS represents the molten salt. After the reaction, the suspension is centrifuged, washed and dried to obtain Ti₃C₂Tₓ MXene. This is the Mxene phase prepared many times in the patent, as shown in FIG. 5 and FIG. 6, which are the element content and SEM photos of Ti₃CCl respectively; FIG. 9 and FIG. 10 are the SEM images of Ti₃C₂Tₓ MXene prepared by molten salt method.

The preparation of Mo₂CTₓ two-dimensional layered structure includes the following steps:

slowly adding 2 g of Mo₂Ga₂C powder into 20 mL HF solution, stirring the mixed solution containing Mo₂Ga₂C in a magnetic stirring heating sleeve at 55° C. for 7 h, and then centrifugalizing it at 10000 rpm for 10 min, harvesting the product and then washing it several times with deionized water until the pH of the solution is 6, drying the obtained powder in a freeze dryer to finally obtain Mo₂CTₓ.

The preparation of V₂CT_{X} two-dimensional layered structure includes the following steps:

because V₂O₃ is easily oxidized in the air, it is difficult to preserve for a long time. Therefore, it is necessary to reduce to V₂O₃ with high melting point by hydrogen. The experimental process of reducing V₂O₅ to V₂O₃ is as follows: in the resistance furnace, continuously introducing hydrogen, heating V₂O₅ to 600° C. for 3 h, then heating it to 1000° C. for 5 h, and finally cooling it with the furnace to obtain V₂O₃.

After mixing V₂O₃, Al₂O₃ and nano-carbon powder (molar ratio of 1:0.75:1) with PVB binder, mixing it with agate mortar for half an hour. Then, pressing 0.5 g of metal oxide/carbon powder mixture by a pressure prototype under 10 MPa pressure to form a cylindrical block with a diameter of 10 mm. The cathode used in the electrolysis process is assembled by the following method: wrapping the block with a stainless steel wire mesh, and then connecting and fixing it on a stainless steel electrode by a stainless steel wire.

The molten salt electrolysis process is carried out in a vertical resistance furnace. The electrolytic cell is composed of a metal oxide/carbon cathode, a graphite anode, an external power supply, and an alumina crucible containing an electrolyte, as shown in FIG. 2. Adding anhydrous CaCl₂) to an alumina crucible (inner diameter: 7 cm, height: 15 cm) and heating in a vacuum oven to 300° C. for 12 h to remove moisture and then using it as an electrolyte.

Continuously introducing high-purity argon into the electrolytic cell to maintain an inert atmosphere during the electrolysis process, and carrying out pre-electrolysis between the Mo rod cathode and the graphite anode at 2.8V for at least 12 h to remove moisture and other impurities in the calcium chloride. The electrolytic cell composed of metal oxide/carbon cathode and graphite anode is electrolyzed at 850° C. and 3.1V electrolysis voltage. Applying direct current through a constant voltage power supply. Washing the obtained cathode product with deionized water to remove the residual calcium chloride molten salt, and drying it in a vacuum oven to obtain the MAX phase powder V₂AlC.

Immersing the V₂AlC powder obtained after 22 h electrolysis in hydrofluoric acid solution to etch the aluminum atomic layer. Slowing adding a total of 1 g V₂AlC powder to 10 mL of 40% HF solution at 35° C. and magnetically stirring for 72 h. Washing the acid mixture with pure water by centrifugation (cycle 3 to 5 times, 8 minutes each time, rotating speed is 3500 rpm). After each cycle, pouring out the acidic supernatant as waste and adding pure water before re-centrifugation. When the PH of the mixture is close to 7, terminating the washing process and drying the mixture in a vacuum oven. Immersing the etched V₂CT_{X} MXene materials in 1 mol/L KOH solution, stirring by magnetic force for 24 h, and then collecting the precipitate by the same centrifugal washing method to obtain two-dimensional V₂CT_{X} MXene.

The tunneling junction structure in the invention uses dense n-type or p-type semiconductor materials as a dense barrier layer, the two-dimensional layered structure material film is used as the tunneling junction composite layer of the perovskite tandem solar cell, combined with the p-type hole transport layer or the n-type electron transport layer corresponding to the dense barrier layer. The tunneling junction composite layer can not only solve the problems of light loss and cell short circuit in the traditional metal tunneling junction composite layer, but also improve the charge transfer, reduce the photocurrent loss and interface series resistance at the tunneling junction, improve the photocurrent and fill factor of the tandem solar cell, and realize the improvement of the power conversion efficiency of the cell. In addition, this method simplifies the preparation process of multi-step high vacuum deposition of metal oxides and metal electrodes in the tunneling junction of traditional perovskite/perovskite tandem solar cell into one-step deposition of two-dimensional layered metal-like materials, which can not only simplify the preparation process of solar cells, reduce the production time, but also make the production cost of solar cells lower, and the preparation process is suitable for the industrial production of large-area solar cell modules.

The two-dimensional layered structure materials used in this invention is a kind of multifunctional material with excellent metal conductivity and abundant surface functional groups. Its work function or band gap can be adjusted by adulteration and passivation, so that selective carrier extraction can be adjusted in the case of low energy loss and limited surface recombination, thereby enhancing the overall performance of solar cells, and the two-dimensional layered materials are used as a tunneling junction. Because the surface functional groups of the two-dimensional layered materials can interact with the organic components in the perovskite layer, the nucleation rate of the perovskite is inhibited and the grain size of the perovskite film is increased, so that the perovskite film has a good crystallization effect. In addition, the two-dimensional layered materials also act as a ‘carrier bridge’ that passes through the grain boundary, accelerating charge transfer, and passivating defects. Besides, the use of two-dimensional layered materials can limit the decomposition of perovskite caused by moisture, thus maintaining the long-term stability of perovskite materials, which provides a way for the preparation of high-performance, large-area, low-cost and stable perovskite solar cells and industrial development.

### BRIEF DESCRIPTION OF THE DRAWINGS

FIG. 1 is a schematic diagram of the device structure of the perovskite/perovskite tandem solar cell in the invention. FIG. 1 (left) is a p-i-n structure perovskite/perovskite tandem solar cell device, and FIG. 1 (right) is an n-i-p perovskite tandem solar cell device.

FIG. 2 is a schematic diagram of the synthesis process of MAX phase powder V₂AlC.

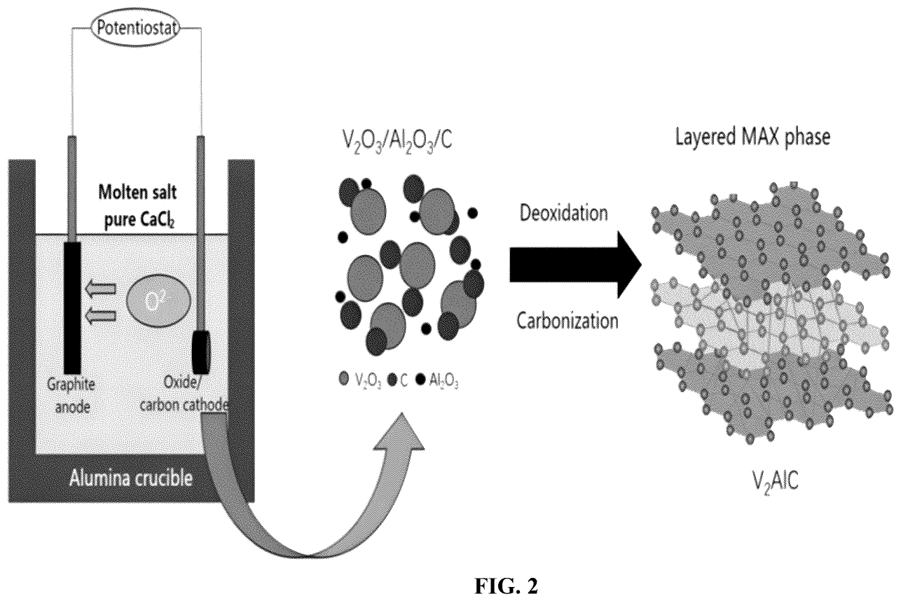

FIG. 3 is the volt-ampere characteristic curve of the p-i-n structure perovskite/perovskite tandem solar cell device in Embodiment 1.

FIG. 4 is the volt-ampere characteristic curve of the n-i-p structure perovskite/perovskite tandem solar cell device in Embodiment 2.

FIG. 5 shows the element content of Ti₃CCl.

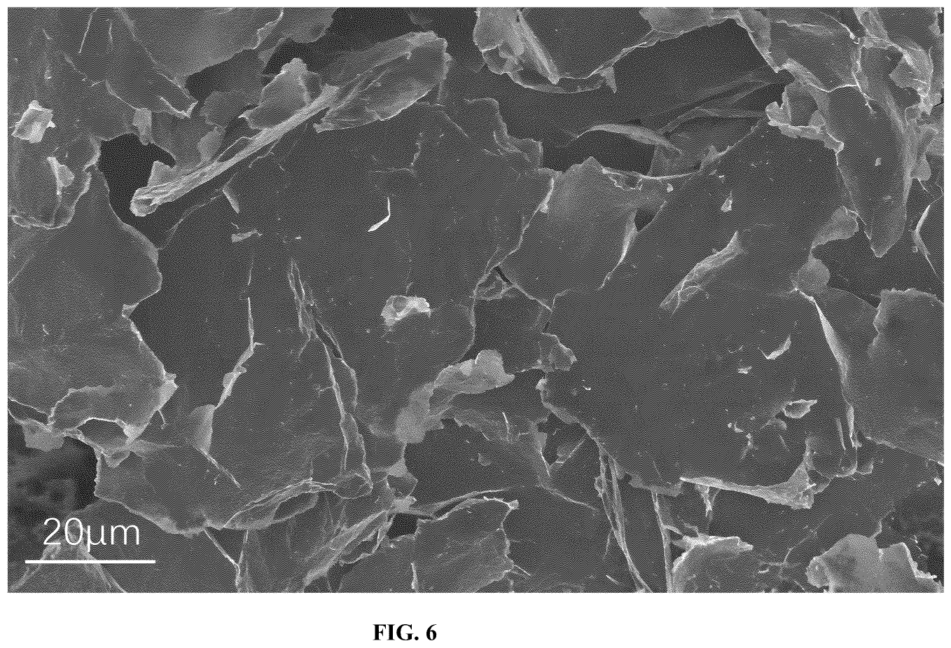

FIG. 6 is the SEM diagram of Ti₃CCl.

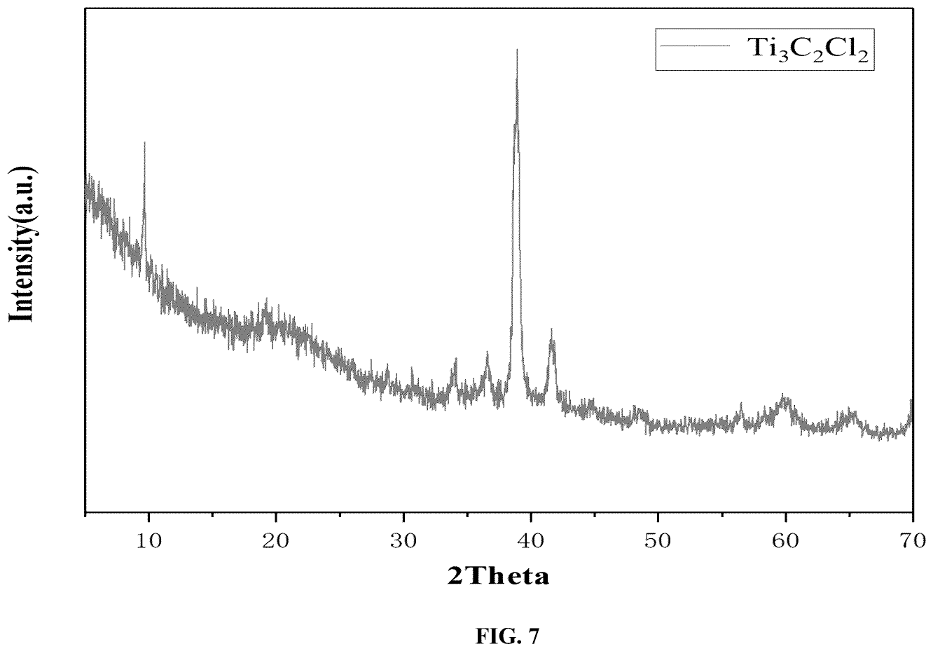

FIG. 7 is the XRD pattern of Ti₃C₂Cl₂ MXene prepared by molten salt method.

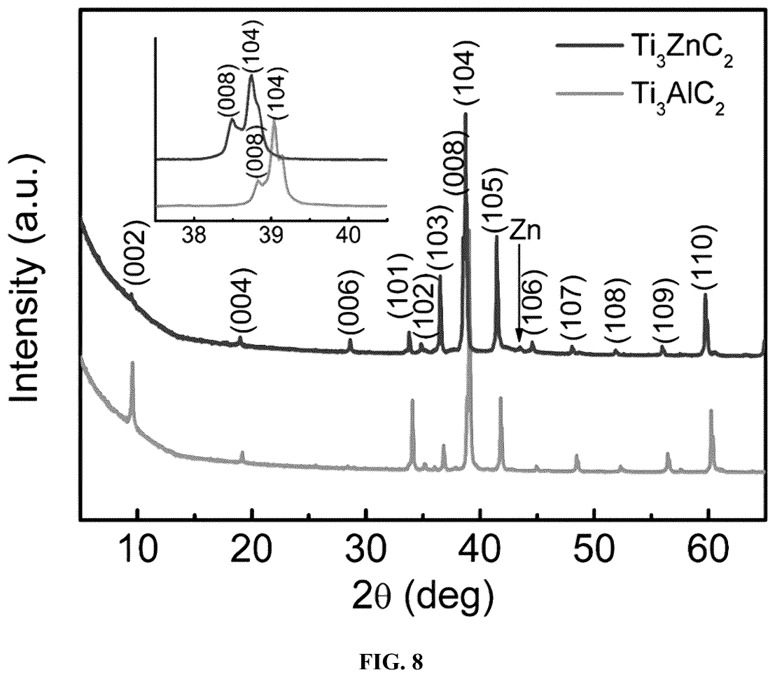

FIG. 8 is the XRD comparison diagram of Ti₃ZnC₂ and Ti₃Al₂C₂.

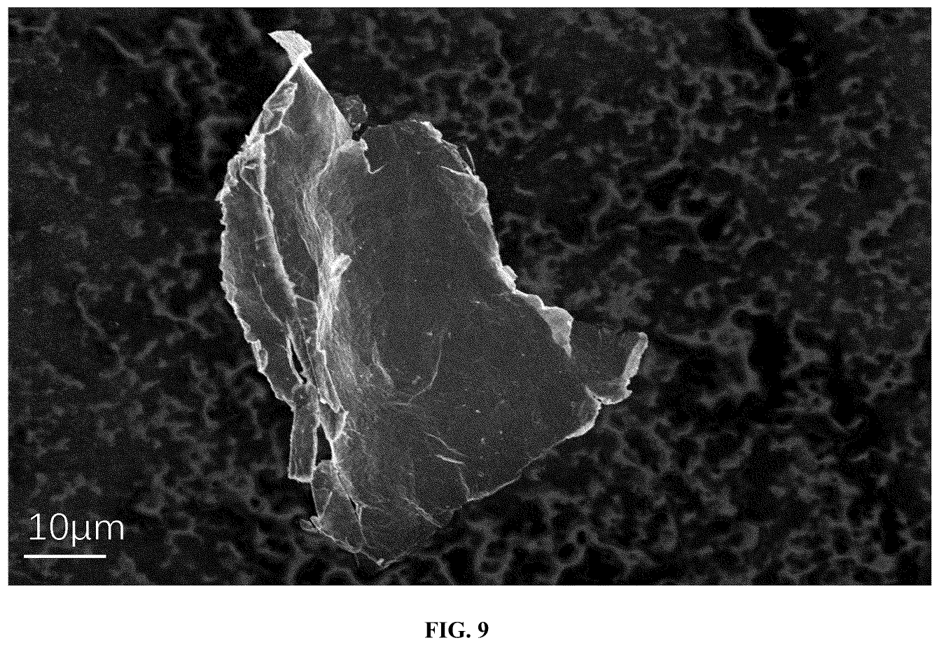

FIG. 9 and FIG. 10 are the SEM diagrams of Ti₃C₂Tₓ MXene prepared by molten salt method.

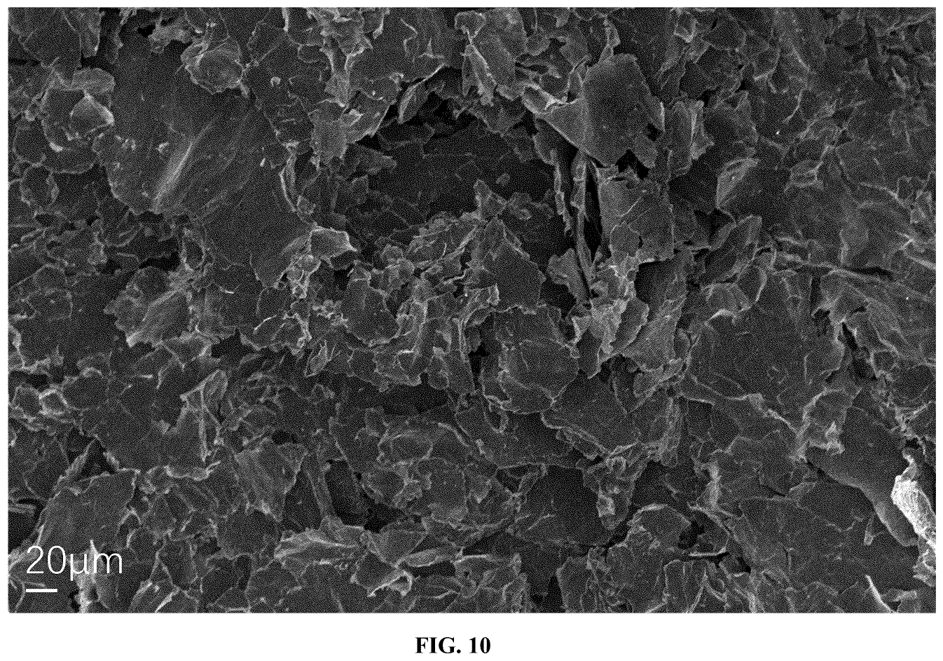

### DETAILED DESCRIPTION OF THE EMBODIMENTS

The following will be combined with the drawings of the embodiments of the invention to clearly and completely describe the technical scheme of the embodiments of the invention. The described embodiments are only part of the embodiments of the invention, not all of the embodiments.

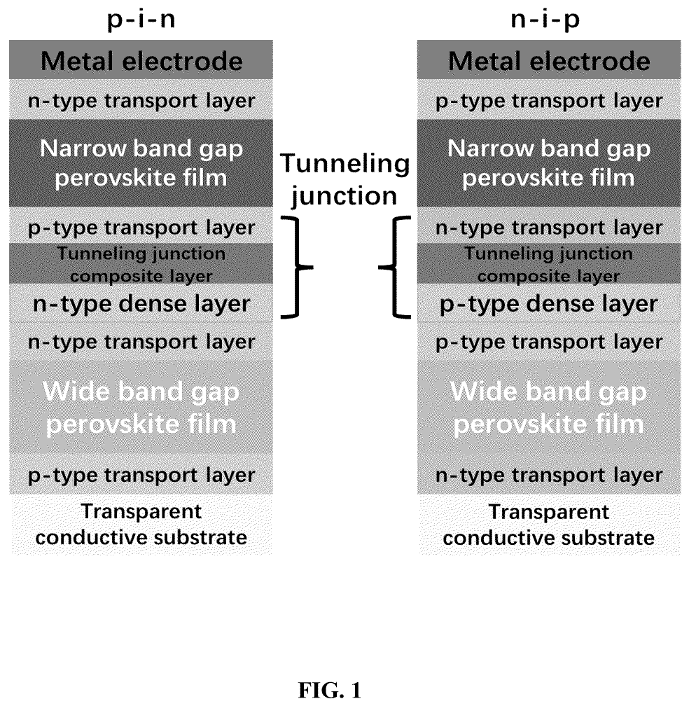

As shown in FIG. 1, the invention designs a tunneling junction structure of perovskite/perovskite tandem solar cell, which is composed of a dense layer, a two-dimensional layered film tunneling junction composite layer and a transport layer. In this structure, the dense layer is prepared by n-type or p-type semiconductor materials, and the transport layer is prepared by the corresponding p-type or n-type semiconductor materials. Among them, n-type semiconductor materials have the ability to transport electrons and block hole transport, and p-type semiconductor materials have the ability to transport holes and block electron transmission.

In the tunneling junction structure of the invention, the n-type or p-type dense layer plays a role in protecting the wide band gap perovskite solar cell (top solar cell) from being destroyed by the subsequent narrow band gap perovskite solar cell (bottom solar cell) in the subsequent preparation process by organic solvent or vacuum sputtering, and the dense layer has the ability to transmit electrons or holes; the two-dimensional layered thin film layer is a tunneling junction composite layer in tandem solar cell. Because of its excellent conductivity, it can play the role of tunneling recombination of electrons or holes and reduce interface charge recombination. At the same time, its excellent light transmittance can allow the incident light to pass through the tunneling junction layer and enter the narrow band gap solar cell, reduce the light loss at the tunneling junction and increase the photocurrent density, thereby improving the power conversion efficiency of the perovskite/perovskite tandem solar cell.

In this invention, a two-dimensional layered thin film layer can be two-dimensional layered structure of metal carbide and metal nitride materials (such as graphene, Ti₃C₂Tₓ, Mo₂CTₓ, V₂CTₓ, Nb₂CTₓ, Ti₂CTₓ, etc.), but not limited to the two-dimensional layered structure materials listed above. The two-dimensional layered film layer can be a continuous two-dimensional layered film, or a two-dimensional layered structure of metal carbide and metal nitride material particle film or a non-dense two-dimensional layered structure of metal carbide and metal nitride material island nanosheet layer. Two-dimensional layered thin film can be prepared by spin coating, scraping, spraying, pulsed laser deposition, magnetron sputtering, chemical vapor deposition and other deposition methods.

The dense layer can be prepared by physical deposition or chemical deposition. Physical deposition methods include but are not limited to vacuum evaporation, sputtering, ion beam deposition, pulsed laser deposition, etc.; chemical deposition methods include but are not limited to chemical vapor deposition, atomic layer deposition, sol-gel, spin coating, etc.

The tunneling junction structure of the invention is applied to the perovskite/perovskite tandem solar photovoltaic cell, and two kinds of perovskite tandem solar cells with different structures of p-i-n and n-i-p can be designed. As shown in FIG. 1 (left), the perovskite tandem solar cell is a p-i-n structure, which includes transparent conductive substrate, p-type hole transport layer, wide band gap perovskite film, n-type electron transport layer, n-type dense layer, tunneling junction composite layer, p-type hole transport layer, narrow band gap perovskite film, n-type electron transport layer and back electrode from bottom to top. As shown in FIG. 1 (right), the n-i-p structure of perovskite tandem solar cells includes transparent conductive substrate, n-type electron transport layer, wide band gap perovskite film, p-type hole transport layer, p-type dense layer, tunneling composite layer, n-type electron transport layer, narrow band gap perovskite film, p-type hole transport layer and back electrode from bottom to top.

Specifically, in the p-i-n structure:

the transparent conductive substrates are indium tin oxide (ITO) and fluorine-doped indium tin oxide (FTO), but not limited to the above listed.

The n-type dense layer or transport layer can be made of one or more n-type semiconductor materials such as titanium oxide (TiO₂), tin oxide (SnO₂), zinc oxide (ZnO), vanadium oxide (V₂O₅), zinc oxide tin (Zn₂SnO₄), but not limited to the n-type semiconductor materials listed above.

The p-type hole transport layer can be prepared by one or more p-type semiconductor materials such as Nickel oxide (NiO), molybdenum oxide (MoO₃), cuprous oxide (Cu₂O), copper iodide (CuI), copper phthalocyanine (CuPc), cuprous thiocyanate (CuSCN), redox graphene, poly [bis(4-phenyl)(2,4,6-trimethylphenyl)amine] (PTAA),2,2′,7,7′-tetra[N,N-bis(4-methoxyphenyl)amino]-9,9′-spirobifluorene (Spiro-OMeTAD), poly(3,4-ethylenedioxythiophene): polystyrene sulfonate (PEDOT:PSS), 4-butyl-N, N-diphenylaniline homopolymer (PloyTPD), and polyvinyl carbazole (PVK), but not limited to the p-type semiconductor materials listed above.

Specifically, in the n-i-p structure:

The p-type dense layer or hole transport layer can be prepared by one or more p-type semiconductor materials such as nickel oxide (NiO), molybdenum oxide (MoO₃), cuprous oxide (Cu₂O), copper iodide (CuI), copper phthalocyanine (CuPc), cuprous thiocyanate (CuSCN), but not limited to the p-type semiconductor materials listed above.

The n-type hole transport layer can be made of one or more n-type semiconductor materials such as titanium oxide (TiO₂), tin oxide (SnO₂), zinc oxide (ZnO), fullerene (C₆₀), graphene, fullerene derivative [6,6]-phenyl-C61-butyric acid methyl ester (PCBM), but not limited to the n-type semiconductor materials listed above.

The following is a further explanation of the above scheme in combination with specific embodiments.

### Embodiment 1

This Embodiment. 1 uses the structure shown in FIG. 1 (left) to prepare perovskite/perovskite tandem solar cell, the specific preparation process is as follows:

1. The ITO conductive glass substrate is put into the detergent, deionized water, isopropanol, anhydrous ethanol for conducting ultrasonic treatment 15˜20 min, and it is also put into the oven at 75° C., and then the cleaned conductive glass substrate is placed in the ultraviolet-ozone device for 20 min to improve the surface wettability of the glass substrate and reduce the defects.

2. Poly[bis(4-phenyl)(2,4,6-trimethylphenyl)amine] (PTAA) is used as a p-type transport layer. 631 mg of PTAA is dissolved in 2 mL of chlorobenzene, the PTAA solution is dropped on the glass substrate and rotated at 2000 rpm for 20s, then the sample is annealed at 120° C. for 10 min to prepare a p-type transport layer with a thickness of about 20 nm.

3. A layer of wide band gap perovskite film is deposited on the basis of the previous step, CH₃NH₃PbI₃ and CH₃NH₃PbBr₃ solutions are prepared by dissolving 124 mg PbCl₂ and 23 mg CH₃NH₃I, 92 mg PbBr₂ and 23 mg CH₃NH₃Br in 2 mL DMF solution respectively. Then CH₃NH₃PbI₃ and CH₃NH₃PbBr₃ solutions are mixed at a ratio of 3:2 to obtain CH₃NH₃Pb (I_{0.6}Br_{0.4})₃ solution, and then 50 μL solution is rotated at 4000 rpm for 60s, and annealed at 100° C. for 1 min, then annealed at 150° C. for 10 min to obtain a layer of wide band gap perovskite film with a thickness of about 300 nm.

4. A layer of fullerene (C₆₀) is prepared by thermal evaporation as an n-type transport layer, the prepared substrate is transferred to the thermal evaporation chamber, and the C₆₀ thin film layer is prepared by high vacuum evaporation coating machine. Firstly, the vacuum degree of the evaporation space is pumped below 10 Pa by a mechanical pump, and a secondary molecular pump is enabled to achieve a high vacuum environment, when the vacuum degree of the evaporation space reaches below 5×10⁻³ Pa, the final preparation of 20 nm C₆₀ film is completed at an evaporation rate of 0.2 Å/s.

5. A layer of SnO₂ is grown on the basis of the previous step by atomic layer deposition (ALD) as an n-type dense layer with a thickness of 20 nm.

6. The tunneling junction composite layer is prepared by spin coating method, the Ti₃C₂Tₓ powder prepared in the early stage is mixed with isopropanol at a mass ratio of 2:7, then the solution is shaken on a vortex machine for 5 min to ensure the uniform texture of the solution, and then the solution is conducted ultrasonic treatment for 15 min, then 70 μL solution is taken to drop the composite layer solution on the glass substrate, and the rotation speed is set at 3500 rpm, the time is 30s. The spin-coated glass is annealed on heating stage at 60° C. for 15 min to obtain a tunneling junction composite layer.

7. A layer of PTAA is prepared by spin coating technology as a p-type transport layer, P3HT solution configuration: 15 mg of P3HT solid powder is dissolved in 1 mL of CB solvent (solution concentration of 15 mg/mL), heated and stirred overnight at 50° C., and then 70 μL of solution is spin-coated at 2000 rpm for 60s without annealing, then the thickness of the obtained P3HT layer is 100 nm.

8. On the basis of the previous step, a layer of narrow band gap perovskite film is deposited, and the precursor solution of FA_{0.7}MA_{0.3}Pb_{0.5}Sn_{0.5}I₃ is prepared, 2M precursor solution is prepared in a mixed solution with a volume ratio of DMF:DMF of 1.5 mL:0.5 mL, the mass of FAI and MAI is 0.2408 g and 0.0954 g respectively; the mass of PbI₂/SnI₂ is 0.4620 g/0.374 g respectively. 0.0374 g of SnF₂ is added to the precursor solution, and the precursor solution is stirred at room temperature for 2 h, the precursor solution is filtered by using 0.20 μm PTFE membrane. In order to reduce the Sn⁴⁺ in the precursor solution, 10 mg of tin powder is added to the precursor and it is stirred at room temperature for 10 min. FA_{0.7}MA_{0.3}Pb_{0.5}Sn_{0.5}I₃perovskite solution is prepared by filtering the precursor solution containing residual tin powder through a 0.20 μm PTFE filter membrane. During the spin coating, a two-step rotation process is used: (1) 1000 rpm/min for 10s, acceleration of 200 rpm/min; (2) 4000 rpm/min for 40s, acceleration of 1000 rpm/min. In the second step of spin coating, ethyl acetate is dripped 20 seconds before the end of the procedure, ethyl acetate is selected because it is less toxic and more environmentally friendly than the commonly used chlorobenzene. The substrate is then transferred to a heating plate and heated at 100° C. for 10 min.

9. A layer of fullerene (C₆₀) and BCP is prepared by thermal evaporation as an n-type transport layer, the final preparation of 20 nm C₆₀ film is completed at an evaporation rate of 0.2 Å/s, and the final preparation of 7 nm BCP film is completed at an evaporation rate of 0.2 Å/s.

10. The metal electrode is deposited by thermal evaporation, and a layer of Cu with a thickness of 120 nm is evaporated at 0.5 Å/s as the metal electrode.

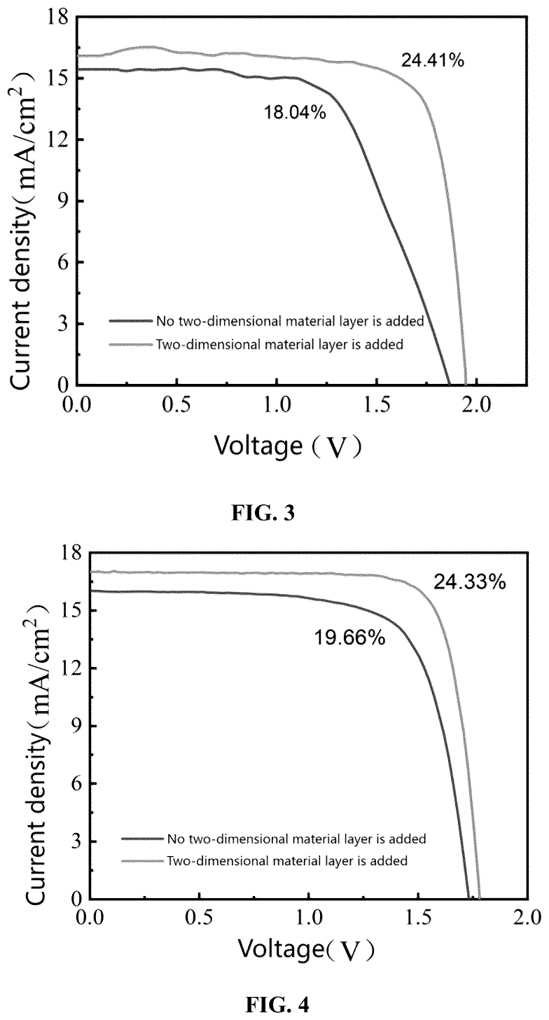

As shown in FIG. 3, the use of two-dimensional layered metal carbides and metal nitrides as the tunneling layer material can not only reduce the loss of incident light, but also provide conductivity and increase the short-circuit current density of the tandem solar cell. In addition, this one-step deposition of two-dimensional layered metal carbide and metal nitride materials has good compactness, which can reduce the voltage loss and improve the open circuit voltage of the tandem solar cell. In the absence of two-dimensional layered film tunneling junction composite layer, the power conversion efficiency of the device is only 18.04%; after preparing a two-dimensional layered film as a tunneling composite layer, the power conversion efficiency can be increased to 24.41%.

### Embodiment 2

This Embodiment 2 uses the structure shown in FIG. 1 (right) to prepare perovskite/perovskite tandem solar cell, the specific preparation process is as follows:

1. The ITO conductive glass substrate is put into the detergent, deionized water, isopropanol, anhydrous ethanol for conducting ultrasonic treatment 15˜20 min, and it is placed in the ultraviolet-ozone device for 20 min to improve the surface wettability of the glass substrate and reduce the defects.

2. A layer of SnO₂ is prepared by chemical bath deposition (CBD) as an n-type transport layer. Firstly, SnCl₂-2H₂O mother liquor needs to be prepared. 5 g urea is dissolved in 400 mL deionized water, and then 100 μL mercaptoacetic acid and 5 mL HCl (37 wt %) are added, finally, 1.096 g SnCl₂-2H₂O powder is dissolved into 0.012M solution, the solution is fully oscillated, mixed and placed in the refrigerator for three days. Then, the SnO₂ layer is deposited, the cleaned ITO conductive glass is put into the UV cleaning machine for 15 min to remove the organic stains on the surface of the glass and improve the surface wettability. 200 μL of standing SnCl₂·2H₂O mother liquor is mixed with 100 mL of deionized water to prepare a 0.02M diluent, and then the treated ITO substrate is immersed in the prepared diluent and placed in an oven at 60° C. for 1 h. After fully reacting, the solution is repeatedly rinsed with deionized water until it is clear and transparent, and then dried by air gun, the CBD steps are repeated twice to ensure the formation of a dense and appropriate thickness of SnO₂ layer. Finally, n-type transport is obtained by annealing at 150° C. on a heating stage for 1 h.

3. A layer of wide band gap perovskite film is deposited on the basis of the previous step. CH₃NH₃PbI₃ and CH₃NH₃PbBr₃ solutions are prepared by dissolving 124 mg PbCl₂ and 23 mg CH₃NH₃I, 92 mg PbBr₂ and 23 mg CH₃NH₃Br in 2 mL DMF solution respectively. Then CH₃NH₃PbI₃ and CH₃NH₃PbBr₃ solutions are mixed at a ratio of 3:2 to obtain CH₃NH₃Pb (I_{0.6}Br_{0.4})₃ solution, and then 50 μL solution is rotated at 4000 rpm for 60s, and annealed at 100° C. for 1 min, then annealed at 150° C. for 10 min to obtain a layer of wide band gap perovskite film with a thickness of about 300 nm.

4. A layer of P3HT is prepared by spin coating technology as a p-type transport layer. P3HT solution configuration: 15 mg of P3HT solid powder is dissolved in 1 mL of CB solvent (solution concentration of 15 mg/mL), heated and stirred overnight at 50° C., and then spin-coated at 2000 rpm for 60s without annealing, the thickness of the obtained P3HT layer is 100 nm.

5. A layer of NiOₓ is grown on the basis of the previous step by atomic layer deposition (ALD) as an p-type dense layer with a thickness of 10 nm.

6. The tunneling junction composite layer is prepared by spin coating method, the Ti₃C₂ Tₓ powder prepared in the early stage is mixed with isopropanol at a mass ratio of 2:7, then the solution is shaken on a vortex machine for 5 min to ensure the uniform texture of the solution, and then the solution is conducted ultrasonic treatment for 15 min to break the large molecular particles, then 70 μL solution is taken to drop the composite layer solution on the glass substrate, and the rotation speed is set at 3500 rpm, the time is 30s. The spin-coated glass is annealed on a heating stage at 60° C. for 15 min to obtain a tunneling junction composite layer.

7. The preparation of C₆₀-n type transport layer is prepared by thermal evaporation technology, the prepared substrate is transferred to the thermal evaporation chamber, and the C₆₀ thin film layer is prepared by high vacuum evaporation coating machine. Firstly, the vacuum degree of the evaporation space is pumped below 10 Pa by a mechanical pump, and a secondary molecular pump is enabled to achieve a high vacuum environment, when the vacuum degree of the evaporation space reaches below 5×10⁻³ Pa, the deposition of 20 nm thin film is completed at an evaporation rate of 0.2 Å/s.

8. On the basis of the prepared C₆₀ layer, a layer of narrow band gap perovskite film is prepared, and the precursor solution of FA_{0.7}MA_{0.3}Pb_{0.5}Sn_{0.5}I₃ is also prepared, 2M precursor solution is prepared in a mixed solution with a volume ratio of DMF:DMF of 1.5 mL:0.5 mL, the mass of FAI and MAI is 0.2408 g and 0.0954 g respectively; the mass of PbI₂/SnI₂ is 0.4620 g/0.374 g respectively. 0.0374 g SnF₂ is added to the precursor solution, and the precursor solution is stirred at room temperature for 2 h, the precursor solution is filtered by using 0.20 μm PTFE membrane. In order to reduce the Sn⁴⁺ in the precursor solution, 10 mg of tin powder is added to the precursor and then it is stirred at room temperature for 10 min for using. FA_{0.7}MA_{0.3}Pb_{0.5}Sn_{0.5}I₃perovskite solution is prepared by filtering the precursor solution containing residual tin powder through a 0.20 μm PTFE filter membrane. During the spin coating, a two-step rotation process is used: (1) 1000 rpm/min for 10s, acceleration of 200 rpm/min; (2) 4000 rpm/min for 40s, acceleration of 1000 rpm/min. In the second step of spin coating, ethyl acetate is dripped 20 seconds before the end of the procedure, ethyl acetate is selected because it is less toxic and more environmentally friendly than the commonly used chlorobenzene. The substrate is then transferred to a heating stage and heated at 100° C. for 10 min.

9. A layer of Spiro-OMeTAD is prepared by spin coating technology as a p-type transport layer. 520 mg of lithium bis (trifluoromethanesulfonyl) imide powder is added to 1 mL of acetonitrile (ACN), and the lithium salt solution is obtained by stirring at room temperature for 3 h in a magnetic stirrer until it is dissolved. 450 mg FK209 powder is added to 1 mL acetonitrile (ACN) and stirred at room temperature for 3 h in a magnetic stirrer to dissolve to obtain FK209 solution. A total of 71 mg Spiro-OMeTAD, 31 μL lithium salt, 25.6 μL TBP solution, 18.5 μL FK209 solution and 1 mL chlorobenzene are added to a 3 mL glass bottle to prepare Spiro-OMeTAD hole transport layer solution, the spin coating instrument program is set to 5000 rpm for 30s, the 40 μL Spiro-OMeTAD solution is weighed by a pipette, and the P-type transport layer is prepared by dynamic spin coating solution on the perovskite film.

10. Finally, by using the thermal evaporation source, a layer of Au with a thickness of 100 nm is evaporated at a speed of 0.5 Å/s as a back electrode.

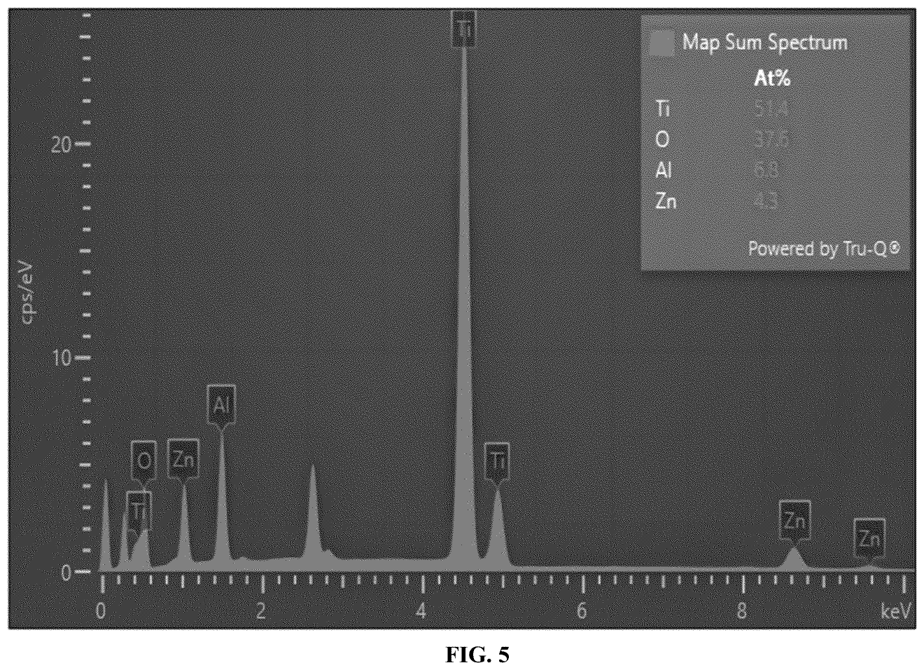

As shown in FIG. 4, using the solar cells prepared in the structure of Embodiment 2 can not only reduce the loss of incident light, but also provide conductivity and increase or decrease the short-circuit current density of the tandem solar cell. In addition, this one-step deposition of two-dimensional layered metal carbide and metal nitride materials has good compactness, which can reduce the voltage loss and improve the open circuit voltage of the tandem solar cell. In the absence of the two-dimensional layered film tunneling junction composite layer, the power conversion efficiency of the device is only 19.66%; after the two-dimensional layered film prepared in Embodiment 2 is used as the tunneling composite layer, the power conversion efficiency is increased to 24.33%.

### Embodiment 3

This Embodiment 3 uses the structure shown in FIG. 1 (left) to prepare perovskite/perovskite tandem solar cell, the specific preparation process is as follows:

1. The ITO conductive glass substrate is put into the detergent, deionized water, isopropanol, anhydrous ethanol for conducting ultrasonic treatment 15˜20 min, and it is also put into the oven at 75° C., and then the cleaned conductive glass substrate is placed in the ultraviolet-ozone device for 20 min to improve the surface wettability of the glass substrate and reduce the defects.

2. Poly[bis(4-phenyl)(2,4,6-trimethylphenyl)amine] (PTAA) is used as a p-type transport layer. 631 mg of PTAA is dissolved in 2 mL of chlorobenzene, the PTAA solution is dropped on the glass substrate and rotated at 2000 rpm for 20s, then the sample is annealed at 120° C. for 10 min to prepare a p-type transport layer with a thickness of about 20 nm.

3. A layer of wide band gap perovskite film is deposited on the basis of the previous step, CH₃NH₃PbI₃ and CH₃NH₃PbBr₃ solutions are prepared by dissolving 124 mg PbCl₂ and 23 mg CH₃NH₃I, 92 mg PbBr₂ and 23 mg CH₃NH₃Br in 2 mL DMF solution respectively. Then CH₃NH₃PbI₃ and CH₃NH₃PbBr₃ solutions are mixed at a ratio of 3:2 to obtain CH₃NH₃Pb (I_{0.6}Br_{0.4})₃ solution, and then 50 μL solution is rotated at 4000 rpm for 60s, and annealed at 100° C. for 1 min, then annealed at 150° C. for 10 min to obtain a layer of wide band gap perovskite film with a thickness of about 300 nm.

4. A layer of fullerene (C₆₀) is prepared by thermal evaporation as an n-type transport layer, the prepared substrate is transferred to the thermal evaporation chamber, and the C₆₀ thin film layer is prepared by high vacuum evaporation coating machine. Firstly, the vacuum degree of the evaporation space is pumped below 10 Pa by a mechanical pump, and a secondary molecular pump is enabled to achieve a high vacuum environment, when the vacuum degree of the evaporation space reaches below 5×10⁻³ Pa, the deposition of 20 nm thin film is completed at an evaporation rate of 0.2 Å/s.

5. A layer of SnO₂ is grown on the basis of the previous step by atomic layer deposition (ALD) as an n-type dense layer with a thickness of 20 nm.

6. The tunneling junction composite layer is prepared by spin coating method, the Mo₂CTₓ powder prepared in the early stage is mixed with isopropanol at a mass ratio of 2:10, then the solution is shaken on a vortex machine for 5 min to ensure the uniform texture of the solution, and then the solution is conducted ultrasonic treatment for 20 min, then 50˜70 μL solution is taken to drop the composite layer solution on the glass substrate, and the rotation speed is set at 5000 rpm for 25s, the spin-coated glass is annealed on a heating stage at 80° C. for 15 min to obtain a tunneling junction composite layer.

7. Poly[bis(4-phenyl)(2,4,6-trimethylphenyl)amine] (PTAA) is used as a p-type transport layer. 631 mg of PTAA is dissolved in 2 mL of chlorobenzene, the PTAA solution is dropped on the glass substrate and rotated at 2000 rpm for 20s, then the sample is annealed at 120° C. for 10 min to prepare a p-type transport layer with a thickness of about 20 nm.

8. On the basis of the previous step, a layer of narrow band gap perovskite film is prepared, and the precursor solution of CsPb_{0.4}Sn_{0.6}I₂Br is also prepared: in a nitrogen-filled glove box, CsI:(PbI₂+PbBr₂):(SnI₂+SnBr₂): SnF₂ is weighed at a stoichiometric molar ratio of 1:0.4:0.6:0.1 and dissolved in an organic mixed solvent of N, N-dimethylformamide and dimethyl sulfoxide (DMF:DMSO=3:7) to prepare a 1 mol/L precursor solution, after stirring at room temperature for 10-12 h, it is filtered by a polytetrafluoroethylene (PTFE) filter head with a pore size of 0.22 μm, and then 50 μL of perovskite precursor solution is taken by a pipette, the perovskite precursor is dropped on the substrate, adjusted to 4000 rpm, and spin-coated for 30s. The spin-coated substrate is annealed on a heating at 120° C. stage for 10 min. A narrow band gap perovskite film with a thickness of about 300 nm is prepared.

9. A layer of C₆₀ and BCP is grown by thermal evaporation technology at 0.2 Å/s evaporation rate as an n-type transport layer, the thickness of C₆₀ is 20 nm and the thickness of BCP is 7 nm.

10. Finally, by using the thermal evaporation source, a layer of Au with a thickness of 100 nm is evaporated at a speed of 0.5 Å/s as a metal electrode.

### Embodiment 4

This Embodiment 4 uses the structure shown in FIG. 1 (right) to prepare perovskite/perovskite tandem solar cell, the specific preparation process is as follows:

1. The ITO conductive glass substrate is put into the detergent, deionized water, isopropanol, anhydrous ethanol for conducting ultrasonic treatment 15˜20 min, and it is also put into the oven at 75° C., and then the cleaned conductive glass substrate is placed in the ultraviolet-ozone device for 20 min to improve the surface wettability of the glass substrate and reduce the defects.

2. A layer of SnO₂ is prepared by chemical bath deposition (CBD) as an n-type transport layer. Firstly, SnCl₂-2H₂O mother liquor needs to be prepared. 5 g urea is dissolved in 400 mL deionized water, and then 100 μL mercaptoacetic acid and 5 mL HCl (37 wt %) are added, finally, 1.096 g SnCl₂-2H₂O powder is dissolved into 0.012M solution, the solution is fully oscillated, mixed and placed in the refrigerator for three days. Then, the SnO₂ layer is deposited. The cleaned ITO conductive glass is put into the UV cleaning machine for 15 min to remove the organic stains on the surface of the glass and improve the surface wettability. 200 μL of standing SnCl₂ 2H₂O mother liquor is mixed with 100 mL of deionized water to prepare a 0.02M diluent, and then the treated ITO substrate is immersed in the prepared diluent and placed in an oven at 60° C. for 1 h. After fully reacting, the solution is repeatedly rinsed with deionized water until it is clear and transparent, and then dried by air gun, the CBD steps are repeated twice to ensure the formation of a dense and appropriate thickness of SnO₂ layer. Finally, n-type transport is obtained by annealing at 150° C. on a heating stage for 1 h.

3. A layer of wide band gap perovskite film is deposited on the basis of the previous step. CH₃NH₃PbI₃ and CH₃NH₃PbBr₃ solutions are prepared by dissolving 124 mg PbCl₂ and 23 mg CH₃NH₃I, 92 mg PbBr₂ and 23 mg CH₃NH₃Br in 2 mL DMF solution respectively. Then CH₃NH₃PbI₃ and CH₃NH₃PbBr₃ solutions are mixed at a ratio of 3:2 to obtain CH₃NH₃Pb (I_{0.6}Br_{0.4})₃ solution, and then 50 μL solution is rotated at 4000 rpm for 60s, and annealed at 100° C. for 1 min, then annealed at 150° C. for 10 min to obtain a layer of wide band gap perovskite film with a thickness of about 300 nm.

4. Poly [bis(4-phenyl)(2,4,6-trimethylphenyl)amine] (PTAA) is used as a p-type transport layer. 631 mg of PTAA is dissolved in 2 ml of chlorobenzene, the PTAA solution is dropped on the glass substrate and rotated at 2000 rpm for 20s, then the sample is annealed at 120° C. for 10 min to prepare a p-type transport layer with a thickness of about 20 nm.

5. A layer of NiOₓ is grown on the substrate by atomic layer deposition (ALD) as a p-type dense layer with a thickness of 10 nm.

6. The tunneling junction composite layer is prepared by spin coating method, the Mo₂CTₓ powder prepared in the early stage is mixed with isopropanol at a mass ratio of 2:10, then the solution is shaken on a vortex machine for 5 min to ensure the uniform texture of the solution, and then the solution is conducted ultrasonic treatment for 20 min to break the large molecular particles, then 50˜70 μL solution is taken to drop the composite layer solution on the glass substrate, and the rotation speed is set at 5000 rpm for 25s. The spin-coated glass is annealed on a heating stage at 60° C. for 15 min to obtain a tunneling junction composite layer.

7. The preparation of C₆₀-n type transport layer is prepared by thermal evaporation technology, the prepared substrate is transferred to the thermal evaporation chamber, and the C₆₀ thin film layer is prepared by high vacuum evaporation coating machine. Firstly, the vacuum degree of the evaporation space is pumped below 10 Pa by a mechanical pump, and a secondary molecular pump is enabled to achieve a high vacuum environment, when the vacuum degree of the evaporation space reaches below 5×10⁻³ Pa, the deposition of 20 nm thin film is completed at an evaporation rate of 0.2 Å/s.

8. On the basis of the prepared Coo layer, a layer of narrow band gap perovskite film is prepared, and the precursor solution of CsPb_{0.4}Sn_{0.6}I₂Br is also prepared: in a nitrogen-filled glove box, CsI:(PbI₂+PbBr₂):(SnI₂+SnBr₂): SnF₂ is weighed at a stoichiometric molar ratio of 1:0.4:0.6:0.1 and dissolved in an organic mixed solvent of N, N-dimethylformamide and dimethyl sulfoxide (DMF:DMSO=3:7) to prepare a 1 mol/L precursor solution, after stirring at room temperature for 10-12 h, it is filtered by a polytetrafluoroethylene (PTFE) filter head with a pore size of 0.22 μm, and then 50 μL of perovskite precursor solution is taken with a pipette, the perovskite precursor is dropped on the substrate, adjusted to 4000 rpm, and spin-coated for 30s. The spin-coated substrate is annealed at 120° C. on a heating stage for 10 min. A narrow band gap perovskite film with a thickness of about 300 nm is prepared.

9. A layer of Spiro-OMeTAD is prepared by spin coating technology as a p-type transport layer. 520 mg of lithium bis (trifluoromethanesulfonyl) imide powder is added to 1 mL of acetonitrile (ACN), and the lithium salt solution is obtained by stirring at room temperature for 3 h in a magnetic stirrer until it is dissolved. 450 mg FK209 powder is added to 1 mL acetonitrile (ACN) and stirred at room temperature for 3 h in a magnetic stirrer to dissolve to obtain FK209 solution. A total of 71 mg Spiro-OMeTAD, 31 μL lithium salt, 25.6 μL TBP solution, 18.5 μL FK209 solution and 1 mL chlorobenzene are added to a 3 mL glass bottle to prepare Spiro-OMeTAD hole transport layer solution, the spin coating instrument program is set to 5000 rpm for 30s, the 40 μL Spiro-OMeTAD solution is weighed by a pipette, and the P-type transport layer with a thickness of about 100 nm is prepared by dynamic spin-coating the solution on the perovskite film.

10. Finally, by using the thermal evaporation source, a layer of Cu with a thickness of 100 nm is evaporated at a speed of 0.5 Å/s as a back electrode.

### Embodiment 5

This Embodiment 5 uses the structure shown in FIG. 1 (left) to prepare perovskite/perovskite tandem solar cell, the specific preparation process is as follows:

1. The ITO conductive glass substrate is put into the detergent, deionized water, isopropanol, anhydrous ethanol for conducting ultrasonic treatment 15˜20 min, and it is also put into the oven at 75° C., and then the cleaned conductive glass substrate is placed in the ultraviolet-ozone device for 20 min to improve the surface wettability of the glass substrate and reduce the defects.

2. NiOₓ: 0.5 mol nickel nitrate hexahydrate is dissolved in 100 mL deionized water to obtain a dark green solution. NaOH solution (10 mol/L) is dropped into nickel nitrate hexahydrate solution until the pH value of the solution is 10. The colloidal precipitate is obtained by stirring at 40° C. for 10 min. The precipitate is washed twice with deionized water, dried at 80° C. for 6 h to obtain green powder, and calcined at 270° C. for 2 h to obtain dark black powder NiOₓ. NiOₓ and isopropanol are configured in a ratio of 3 mg:1 ml, and 80 μL of NiOₓ aqueous solution is spin-coated on a cleaned ITO substrate at a speed of 3000 rpm/min for 30s. Then the sample is annealed at 110° C. for 20 min to obtain nickel oxide p-type transport layer.

3. A layer of wide band gap perovskite film is deposited on the basis of the previous step, CH₃NH₃PbI₃ and CH₃NH₃PbBr₃ solutions are prepared by dissolving 124 mg PbCl₂ and 23 mg CH₃NH₃I, 92 mg PbBr₂ and 23 mg CH₃NH₃Br in 2 mL DMF solution respectively. Then CH₃ NH₃PbI₃ and CH₃NH₃PbBr₃ solutions are mixed at a ratio of 3:2 to obtain CH₃NH₃Pb (I_{0.6}Br_{0.4})₃ solution, and then 50 μL solution is rotated at 4000 rpm for 60s, and annealed at 100° C. for 1 min, then annealed at 150° C. for 10 min to obtain a layer of wide band gap perovskite film with a thickness of about 300 nm.

4. ZnO nanoparticles: 1.96 g of zinc acetate dihydrate (C₄H₁₀O₆Zn) is dissolved in 60 mL of anhydrous ethanol and stirred for 30 min, the obtained solution is transferred to a 100 mL hydrothermal kettle and heated at 150° C. for 12 h. After heating, the solution is cooled to room temperature, the supernatant is removed, the precipitate is washed twice with ethanol water, dried overnight at 60° C., and then calcined at 480° C. for 3 h to obtain white powder, then ZnO powder is dispersed in butanol with a concentration of 10 mg/mL to deposit an electron transfer layer (ETL), and the n-type transport layer is obtained by spin coating at 4000 rpm for 60s and annealing for 10 min.

5. A layer of C₆₀ is grown on the basis of the previous step by using thermal evaporation technology at an evaporation rate of 0.2 Å/s as an n-type dense layer with a thickness of 20 nm.

6. The solution is prepared by mixing the V₂CTX powder prepared in the early stage with isopropanol at a mass ratio of 2:13, and then the solution is shaken on the vortex machine for 5 min to ensure the uniform texture of the solution, and then the solution is conducted ultrasonic treatment for 20 min, after fixing the substrate on the coating machine platform, the surface of the substrate is slowly pressed on the surface of the substrate by a four-sided preparation device, and then the load-bearing weight crank of the coating machine is slowly pressed on the top of the four-sided preparation. At the same time, anhydrous ether and n-hexane are poured into a square container at a ratio of 1:1 and mixed evenly. The mixed solution is coated on the upper edge of the substrate (50-75 μL) by using a pipette, the coating machine is selected to work at a speed of 5 mm/s. After the coating is completed, the substrate with a wet film is quickly immersed in a mixed solution of ether and n-hexane for anti-solvent treatment for 2 min. And after that, the substrate is placed on a temperature-controlled heating stage and annealed at 150° C. for 30 min to prepare a tunneling junction film.

7. Poly[bis(4-phenyl)(2,4,6-trimethylphenyl)amine] (PTAA) is used as a p-type transport layer. 631 mg of PTAA is dissolved in 2 mL of chlorobenzene, the PTAA solution is dropped on the glass substrate and rotated at 2000 rpm for 20s, then the sample is annealed at 120° C. for 10 min to prepare a p-type transport layer with a thickness of about 20 nm.

8. On the basis of the previous step, a layer of narrow band gap perovskite film is prepared, and the precursor solution of CsPb_{0.4}Sn_{0.6}I₂Br is also prepared: in a nitrogen-filled glove box, CsI:(PbI₂+PbBr₂):(SnI₂+SnBr₂): SnF₂ is weighed at a stoichiometric molar ratio of 1:0.4:0.6:0.1 and dissolved in an organic mixed solvent of N, N-dimethylformamide and dimethyl sulfoxide (DMF:DMSO=3:7) to prepare a 1 mol/L precursor solution, after stirring at room temperature for 10-12 h, it is filtered by a polytetrafluoroethylene (PTFE) filter head with a pore size of 0.22 μm, and then 50 μL of perovskite precursor solution is taken with a pipette, the perovskite precursor is dropped on the substrate, adjusted to 4000 rpm, and spin-coated for 30s. The spin-coated substrate is annealed at 120° C. on a heating stage for 10 min. A narrow band gap perovskite film with a thickness of about 300 nm is prepared.

9. A layer of C₆₀ and BCP is grown by thermal evaporation technology at 0.2 Å/s evaporation rate as an n-type transport layer, the thickness of C₆₀ is 20 nm and the thickness of BCP is 7 nm.

10. Finally, by using the thermal evaporation source, a layer of Au with a thickness of 100 nm is evaporated at a speed of 0.5 Å/s as a metal electrode.

### Embodiment 6

This Embodiment 6 uses the structure shown in FIG. 1 (right) to prepare perovskite/perovskite tandem solar cell, the specific preparation process is as follows:

1. The ITO conductive glass substrate is put into the detergent, deionized water, isopropanol, anhydrous ethanol for conducting ultrasonic treatment 15˜20 min, and it is also put into the oven at 75° C., and then the cleaned conductive glass substrate is placed in the ultraviolet-ozone device for 20 min to improve the surface wettability of the glass substrate and reduce the defects.

2. A layer of SnO₂ is prepared by chemical bath deposition (CBD) as an n-type transport layer. Firstly, SnCl₂-2H₂O mother liquor needs to be prepared. 5 g urea is dissolved in 400 mL deionized water, and then 100 μL mercaptoacetic acid and 5 mL HCl (37 wt %) are added, finally, 1.096 g SnCl₂-2H₂O powder is dissolved into 0.012M solution, the solution is fully oscillated, mixed and placed in the refrigerator for three days. Then, the SnO₂ layer is deposited, the cleaned ITO conductive glass is put into the UV cleaning machine for 15 min to remove the organic stains on the surface of the glass and improve the surface wettability. 200 μL of standing SnCl₂ 2H₂O mother liquor is mixed with 100 mL of deionized water to prepare a 0.02M diluent, and then the treated ITO substrate is immersed in the prepared diluent and placed in an oven at 60° C. for 1 h. After fully reacting, the solution is repeatedly rinsed with deionized water until it is clear and transparent, and then dried by air gun, the CBD steps are repeated twice to ensure the formation of a dense and appropriate thickness of SnO₂ layer. Finally, n-type transport is obtained by annealing at 150° C. on a heating stage for 1 h.

3. A layer of wide band gap perovskite film is deposited on the basis of the previous step. CH₃NH₃PbI₃ and CH₃NH₃PbBr₃ solutions are prepared by dissolving 124 mg PbCl₂ and 23 mg CH₃ NH₃I, 92 mg PbBr₂ and 23 mg CH₃NH₃Br in 2 mL DMF solution respectively. Then CH₃NH₃PbI₃ and CH₃NH₃PbBr₃ solutions are mixed at a ratio of 3:2 to obtain CH₃NH₃Pb (I_{0.6}Br_{0.4})₃ solution, and then 50 μL solution is rotated at 4000 rpm for 60s, and annealed at 100° C. for 1 min, then annealed at 150° C. for 10 min to obtain a layer of wide band gap perovskite film with a thickness of about 300 nm.

4. Poly[bis(4-phenyl)(2,4,6-trimethylphenyl)amine] (PTAA) is used as a hole transport layer. 631 mg of PTAA is dissolved in 2 mL of chlorobenzene, and the PTAA solution is dropped on the glass substrate, rotated at 2000 rpm for 20s, and then the sample is annealed at 120° C. for 10 min to prepare a p-type transport layer with a thickness of 20 nm.

5. A layer of NiOₓ is grown on the substrate by atomic layer deposition (ALD) as a p-type dense layer with a thickness of 10 nm.

6. The solution is prepared by mixing the V₂CTₓ powder prepared in the early stage with isopropanol at a mass ratio of 2:13, and the solution is shaken on the vortex machine for 5 min to ensure the uniform texture of the solution, and then the solution is conducted ultrasonic treatment for 20 min, after fixing the substrate on the coating machine platform, the surface of the substrate is slowly pressed by a four-sided preparation device, and then the load-bearing weight crank of the coating machine is slowly pressed on the top of the four-sided preparation. At the same time, anhydrous ether and n-hexane are poured into a square container at a ratio of 1:1 and mixed evenly. The mixed solution is coated on the upper edge of the substrate (50-75 μL) by using a pipette, the coating machine is selected to work at a speed of 5 mm/s. After the coating is completed, the substrate with a wet film is quickly immersed in a mixed solution of ether and n-hexane for anti-solvent treatment for 2 min. And after that, the substrate is placed on a temperature-controlled heating stage and annealed at 150° C. for 30 min to prepare a tunneling junction film.

7. A layer of fullerene (C₆₀) is prepared by thermal evaporation as an n-type transport layer, the prepared substrate is transferred to the thermal evaporation chamber, and the C₆₀ film layer is prepared by high vacuum evaporation coating machine. Firstly, the vacuum degree of the evaporation space is pumped below 10 Pa by a mechanical pump, and a secondary molecular pump is enabled to achieve a high vacuum environment, when the vacuum degree of the evaporation space reaches below 5×10⁻³ Pa, the deposition of 20 nm thin film is completed at an evaporation rate of 0.2 Å/s.

8. On the basis of the prepared C₆₀ layer, a layer of narrow band gap perovskite film is prepared, and the precursor solution of CsPb_{0.4}Sn_{0.6}I₂Br is also prepared: in a nitrogen-filled glove box, CsI:(PbI₂+PbBr₂):(SnI₂+SnBr₂): SnF₂ is weighed at a stoichiometric molar ratio of 1:0.4:0.6:0.1 and dissolved in an organic mixed solvent of N, N-dimethylformamide and dimethyl sulfoxide (DMF:DMSO=3:7) to prepare a 1 mol/L precursor solution, after stirring at room temperature for 10-12 h, it is filtered by a polytetrafluoroethylene (PTFE) filter head with a pore size of 0.22 μm, and then 50 μL of perovskite precursor solution is taken by a pipette, the perovskite precursor is dropped on the substrate, adjusted to 4000 rpm, and spin-coated for 30s. The spin-coated substrate is annealed at 120° C. on a heating stage for 10 min. A narrow band gap perovskite film with a thickness of about 300 nm is prepared.

9. A layer of Spiro-OMeTAD is prepared by spin coating technology as a p-type transport layer. 520 mg of lithium bis (trifluoromethanesulfonyl) imide powder is added to 1 mL of acetonitrile (ACN), and the lithium salt solution is obtained by stirring at room temperature for 3 h in a magnetic stirrer until it is dissolved. Then 101 mg Spiro-OMeTAD, 34 μL lithium salt, 25.4 μL TBP solution and 1 ml chlorobenzene are added to a 3 mL glass bottle to prepare Spiro-OMeTAD hole transport layer solution, the spin coating instrument program is set to 5000 rpm for 30s, the 40 μL Spiro-OMeTAD solution is weighed by a pipette, and the hole transport layer is prepared by dynamic spin-coating the hole solution on the perovskite film.

10. Finally, by using the thermal evaporation source, a layer of Cu with a thickness of 120 nm is evaporated at a speed of 0.5 Å/s as a back electrode.

### Embodiment 7

This Embodiment 7 uses the structure shown in FIG. 1 (left) to prepare perovskite/perovskite tandem solar cell, the specific preparation process is as follows:

1. The ITO conductive glass substrate is put into the detergent, deionized water, isopropanol, anhydrous ethanol for conducting ultrasonic treatment 15 min, and it is also put into the oven at 80° C. for drying, and then the cleaned conductive glass substrate is placed in the ultraviolet-ozone device for 20 min to improve the surface wettability of the glass substrate and reduce the defects.

2. NiOₓ: 0.5 mol nickel nitrate hexahydrate is dissolved in 100 mL deionized water to obtain a dark green solution. NaOH solution (10 mol/L) is dropped into nickel nitrate hexahydrate solution until the pH value of the solution is 10. The colloidal precipitate is obtained by stirring at 40° C. for 10 min. The precipitate is washed twice with deionized water, dried at 80° C. for 6 h to obtain green powder, and calcined at 270° C. for 2 h to obtain dark black powder NiOₓ. NiOₓ and isopropanol are configured in a ratio of 3 mg:1 ml, and 80 μL of NiOₓ aqueous solution is spin-coated on a cleaned ITO substrate at a speed of 3000 rpm/min for 30s. Then the sample is annealed at 110° C. for 20 min to obtain nickel oxide p-type transport layer.

3. On the basis of the previous step, a wide band gap perovskite film is deposited, and the CsPbBr₃ film is prepared by two-step deposition method. 1M PbBr₂ is dissolved in 2 mL DMF solution, heated and stirred at 75° C. for 20 min, and then filtered with a 0.5 μm polytetrafluoroethylene filter, a certain amount of solution is spin-coated on the substrate at a speed of 2500 rpm/min, and then annealed at 75° C. for 10 min. After cooling to room temperature, 1.5M CsBr is dissolved in 2 mL methanol solution, and a certain amount of solution is spin-coated on the substrate at a speed of 4500 rpm/min, and then annealed at 250° C. for 15 min. Thus, a layer of CsPbBr₃ film is prepared.

4. A layer of fullerene (C₆₀) is prepared by thermal evaporation as an n-type transport layer, the prepared substrate is transferred to the thermal evaporation chamber, and the C₆₀ film layer is prepared by high vacuum evaporation coating machine. Firstly, the vacuum degree of the evaporation space is filtered to below 10 Pa by a mechanical pump, and a secondary molecular pump is used to achieve a high vacuum environment, when the vacuum degree of the evaporation space reached below 5×10⁻³ Pa, the established evaporation process is started, and the deposition of 20 nm thin film is completed at an evaporation rate of 0.2 Å/s.

5. A layer of SnO₂ is prepared on the substrate by atomic layer deposition (ALD) as a n-type dense layer with a thickness of 20 nm.

6. The solution is prepared by mixing the Ti₃C₂Tₓ powder prepared in the early stage with isopropanol at a mass ratio of 2:7, and then the solution is shaken on the vortex machine for 5 min to ensure the uniform texture of the solution, and then the solution is conducted ultrasonic treatment for 15 min, then 70 μL solution is taken to drop the composite layer solution on the glass substrate, and the rotation speed is set at 3500 rpm for 30s. The spin-coated glass is annealed on a heating stage at 60° C. for 15 min to obtain a tunneling junction composite layer.

7. Poly[bis(4-phenyl)(2,4,6-trimethylphenyl)amine] (PTAA) is used as a hole transport layer. 631 mg of PTAA is dissolved in 2 mL of chlorobenzene, the PTAA solution is dropped on the glass substrate and rotated at 2000 rpm for 20s, then the sample is annealed at 120° C. for 10 min to prepare a p-type transport layer with a thickness of about 20 nm.

8. On the basis of the previous step, a layer of narrow band gap perovskite film is prepared, and the precursor solution of CsPb_{0.4}Sn_{0.6}I₂Br is also prepared: in a nitrogen-filled glove box, CsI:(PbI₂+PbBr₂):(SnI₂+SnBr₂): SnF₂ is weighed at a stoichiometric molar ratio of 1:0.4:0.6:0.1 and dissolved in an organic mixed solvent of N, N-dimethylformamide and dimethyl sulfoxide (DMF:DMSO=3:7) to prepare a 1 mol/L precursor solution, after stirring at room temperature for 10-12 h, it is filtered by a polytetrafluoroethylene (PTFE) filter head with a pore size of 0.22 μm, and then 50 μL of perovskite precursor solution is taken by using a pipette, the perovskite precursor is dropped on the substrate, adjusted to 4000 rpm, and spin-coated for 30s. The spin-coated substrate is annealed at 120° C. on a heating stage for 10 min. A narrow band gap perovskite film with a thickness of about 300 nm is prepared.

9. A layer of C₆₀ and BCP is grown by thermal evaporation technology at 0.2 Å/s evaporation rate as an n-type transport layer, the thickness of C₆₀ is 20 nm and the thickness of BCP is 7 nm.

10. Finally, by using the thermal evaporation source, a layer of Au with a thickness of 100 nm is evaporated at a speed of 0.5 Å/s as a metal electrode.

### Embodiment 8

This Embodiment 8 uses the structure shown in FIG. 1 (right) to prepare perovskite/perovskite tandem solar cell, the specific preparation process is as follows:

1. The ITO conductive glass substrate is put into the detergent, deionized water, isopropanol, anhydrous ethanol for conducting ultrasonic treatment 15˜20 min, and it is also put into the oven at 75° C., and then the cleaned conductive glass substrate is placed in the ultraviolet-ozone device for 20 min to improve the surface wettability of the glass substrate and reduce the defects.

2. A layer of SnO₂ is prepared by chemical bath deposition (CBD) as an n-type transport layer. Firstly, SnCl₂-2H₂O mother liquor needs to be prepared. 5 g urea is dissolved in 400 mL deionized water, and then 100 μL mercaptoacetic acid and 5 mL HCl (37 wt %) are added, finally, 1.096 g SnCl₂-2H₂O powder is dissolved into 0.012M solution, the solution is fully oscillated, mixed and placed in the refrigerator for three days. Then, the SnO₂ layer is deposited, the cleaned ITO conductive glass is put into the UV cleaning machine for 15 min to remove the organic stains on the surface of the glass and improve the surface wettability. 200 μL of standing SnCl₂ 2H₂O mother liquor is mixed with 100 mL of deionized water to prepare a 0.02M diluent, and then the treated ITO substrate is immersed in the prepared diluent and placed in an oven at 60° C. for 1 h. After fully reacting, the solution is repeatedly rinsed with deionized water until it is clear and transparent, and then dried by air gun, the CBD steps are repeated twice to ensure the formation of a dense and appropriate thickness of SnO₂ layer. Finally, n-type transport layer is obtained by annealing at 150° C. on a heating stage for 1 h.

3. On the basis of the previous step, a wide band gap perovskite film is deposited, and the CsPbBr₃ film is prepared by two-step deposition method. 1M PbBr₂ is dissolved in 2 mL DMF solution, heated and stirred at 75° C. for 20 min, and then filtered with a 0.5 μm polytetrafluoroethylene filter, a certain amount of solution is spin-coated on the substrate at a speed of 2500 rpm/min, and then annealed at 75° C. for 10 min. After cooling to room temperature, 1.5M CsBr is dissolved in 2 mL methanol solution, and a certain amount of solution is spin-coated on the substrate at a speed of 4500 rpm/min, and then annealed at 250° C. for 15 min. Thus, a layer of CsPbBr₃ film is prepared.

4. Poly[bis(4-phenyl)(2,4,6-trimethylphenyl)amine] (PTAA) is used as a hole transport layer. 631 mg of PTAA is dissolved in 2 mL of chlorobenzene, and the PTAA solution is dropped on the glass substrate, rotated at 2000 rpm for 20s, and then the sample is annealed at 120° C. for 10 min to prepare a p-type transport layer with a thickness of 20 nm.

5. A layer of NiOₓ is grown on the substrate by atomic layer deposition (ALD) as a p-type dense layer with a thickness of 10 nm.

6. The solution is prepared by mixing the Ti₃C₂Tₓ powder prepared in the early stage with isopropanol at a mass ratio of 2:7, and then the solution is shaken on the vortex machine for 5 min to ensure the uniform texture of the solution, and then the solution is conducted ultrasonic treatment for 15 min, then 70 μL solution is taken to drop the composite layer solution on the glass substrate, and the rotation speed is set at 3500 rpm for 30s. The spin-coated glass is annealed on a heating stage at 60° C. for 15 min to obtain a tunneling junction composite layer.

7. A layer of SnO₂ is grown on the substrate by atomic layer deposition (ALD) as an n-type dense layer with a thickness of 10 nm.

8. On the basis of the previous step, a layer of narrow band gap perovskite film is prepared, and the precursor solution of CsPb_{0.4}Sn_{0.6}I₂Br is also prepared: in a nitrogen-filled glove box, CsI:(PbI₂+PbBr₂):(SnI₂+SnBr₂): SnF₂ is weighed at a stoichiometric molar ratio of 1:0.4:0.6:0.1 and dissolved in an organic mixed solvent of N, N-dimethylformamide and dimethyl sulfoxide (DMF:DMSO=3:7) to prepare a 1 mol/L precursor solution, after stirring at room temperature for 10-12 h, it is filtered by a polytetrafluoroethylene (PTFE) filter head with a pore size of 0.22 μm, and then 50 μL of perovskite precursor solution is taken by using a pipette, the perovskite precursor is dropped on the substrate, adjusted to 4000 rpm, and spin-coated for 30s. The spin-coated substrate is annealed at 120° C. on a heating stage for 10 min. A narrow band gap perovskite film with a thickness of about 300 nm is prepared.

9. A layer of Spiro-OMeTAD is prepared by spin coating technology as a p-type transport layer. 520 mg of lithium bis (trifluoromethanesulfonyl) imide powder is added to 1 mL of acetonitrile (ACN), and the lithium salt solution is obtained by stirring at room temperature for 3 h in a magnetic stirrer until it is dissolved. Then 101 mg Spiro-OMeTAD, 34 μL lithium salt, 25.4 μL TBP solution and 1 ml chlorobenzene are added to a 3 mL glass bottle to prepare Spiro-OMeTAD hole transport layer solution, the spin coating instrument program is set to 5000 rpm for 30s, the 40 μL Spiro-OMeTAD solution is weighed by a pipette, and the hole transport layer is prepared by dynamic spin-coating the hole solution on the perovskite film.

10. Finally, by using the thermal evaporation source, a layer of Au with a thickness of 100 nm is evaporated at a speed of 0.5 Å/s as a back electrode.

What is claimed is:

1. Perovskite tandem solar cells based on a tunneling layer of two-dimensional layered metal carbides and metal nitrides: a tunneling junction composite layer is prepared by using two-dimensional layered metal carbides and metal nitrides, a dense layer is arranged on one side of the tunneling junction composite layer, and a transport layer is arranged on the other side;
the two-dimensional layered metal carbide and metal nitride materials are selected from graphene, Ti3C2Tx, Mo2CTx, V2CTx, Nb2CTx, Ti2CTx.

2. The perovskite tandem solar cells according to claim 1, the dense layer is prepared by n-type semiconductor materials, and the transport layer is prepared by p-type semiconductor materials; or, the dense layer is prepared by p-type semiconductor materials, and the transport layer is prepared by n-type semiconductor materials.

3. The perovskite tandem solar cells according to claim 1, perovskite tandem solar cells based on a tunneling layer of two-dimensional layered metal carbides and metal nitrides, the structure of the perovskite/perovskite tandem solar cell described in this paper is p-i-n type, which includes conductive substrate, p-type hole transport layer, wide band gap perovskite film, n-type electron transport layer, n-type dense layer, tunneling junction composite layer, p-type hole transport layer, narrow band gap perovskite film, n-type electron transport layer and metal back electrode from bottom to top;
or, the structure of the perovskite/perovskite tandem solar cell is n-i-p type, which includes transparent conductive substrate, n-type electron transport layer, wide band gap perovskite film, p-type hole transport layer, p-type dense layer, tunneling junction composite layer, n-type electron transport layer, narrow band gap perovskite film, p-type hole transport layer and metal back electrode from bottom to top.

4. The perovskite tandem solar cells according to claim 1, the preparation of Ti₃C₂Tₓ two-dimensional layered structure material includes the following steps:
Step 1: firstly, under the protection of nitrogen in the glove box, weighing the raw materials according to the ratio of TiC:Ti:Si:NaCl:KCl=2:1:1.1:4:4, then, thoroughly mixing the weighed raw materials, and taking out the obtained mixed powder from the glove box and putting it into the planetary ball mill to fully mash for 5 h, and putting the mashed powder into the alumina crucible; then putting the alumina crucible into a tube furnace, and conducting heat treatment at a rate of 4° C./min to 1100° C. for 3 h under the protection of argon atmosphere, after the reaction, cooing the tube furnace to room temperature at a rate of 4° C./min, and then removing NaCl and KCl by washing with deionized water, drying the residual product at 60° C. to obtain the Si-MAX phase precursor;
Step 2: under the protection of nitrogen in the glove box, thoroughly mixing the raw materials according to the molar ratio of Si-MAX phase precursor:ZnCl2=1:6, and then taking out the obtained mixed powder from the glove box and placing it in a planetary ball mill for 3 h, and then placing the powder in an alumina crucible; putting the alumina crucible into a tube furnace and conducting heat treatment at 550° C. for 5 h under argon protection; after the reaction, removing the residual ZnCl2 by washing with deionized water, and obtaining the reaction product Ti3SiC2 MAX phase by drying at 40° C.;
Step 3: immersing the prepared Ti3SiC2 MAX phase in molten CuCl2 Lewis molten salt at 750° C. for 6 h, the Si atoms weakly bound to Ti in the Ti₃C₂ sublayer, which are oxidized to Si4+ cation by Lewis acid Cu2+, so as to form a volatile SiCl4 phase, at the same time, Cu2+ is reduced to Cu metal, Ti3SiC2 reacts with CuCl2 to form Ti3C2Cl2; further immersing Ti3C2Cl2 powder and Cu metal in ammonium persulfate solution to remove Cu particles on the surface and increase O-surface groups, after the reaction, centrifugalizing, washing and drying the suspension to obtain Ti3C2Tx MXene.

5. The perovskite tandem solar cells according to claim 1, Mo2CTx two-dimensional layered structure material is prepared by the following method:
slowly adding 2 g of Mo2Ga2C powder into 20 mL HF solution, stirring the mixed solution containing Mo2Ga2C in a magnetic stirring heating sleeve at 55° C. for 7 h, and then centrifugalizing it at 10000 rpm for 10 min, harvesting the product and then washing it several times with deionized water until the pH of the solution is 6, drying the obtained powder in a freeze dryer to finally obtain Mo2CTx.

6. The perovskite tandem solar cells according to claim 1, the preparation of V2CTX two-dimensional layered structure material includes the following steps:
(1) in the resistance furnace, continuously introducing hydrogen, heating V2O5 to 600° C. for 3 h, then heating to 1000° C. for 5 h, and finally cooling with the furnace to obtain V2O3;
(2) after mixing V2O3, Al₂O₃ and nano-carbon powder with PVB binder, mixing it with agate mortar for half an hour, then, pressing 0.5 g of metal oxide/carbon powder mixture by a pressure prototype under 10 MPa pressure to form a cylindrical block with a diameter of 10 mm, which is used as the cathode material;
(3) carrying out the molten salt electrolysis process in a vertical resistance furnace; the electrolytic cell is composed of a metal oxide/carbon cathode, a graphite anode, an external power supply, and an alumina crucible containing an electrolyte; continuously introducing high-purity argon into the electrolytic cell, and performing electrolysis between the cathode and the graphite anode at 2.8V for at least 12 h to remove moisture and other impurities in calcium chloride; the electrolytic cell composed of metal oxide/carbon cathode and graphite anode is electrolyzed at 850° C. and 3.1V electrolysis voltage, applying direct current through a constant voltage power supply, washing the obtained cathode product with deionized water to remove the residual calcium chloride molten salt, and drying it in a vacuum oven to obtain the MAX phase powder V2AlC;
(4) immersing the V2AlC powder obtained after electrolysis in hydrofluoric acid solution to etch the aluminum atom layer, and immersing the etched V2CTX MXene material in 1 mol/L KOH solution, then stirring it with a magnetic stirrer for 24 h, collecting the precipitate by centrifugation and washing it to obtain two-dimensional V2CTX MXene material.
